(19) United States
(12) Patent Application Publication
(10) Pub. No.: US 2026/0126483 A1
(43) Pub. Date: May 7, 2026

(54) APPARATUS AND METHOD FOR PROBING DEVICE-UNDER-TEST

(71) Applicant: Taiwan Semiconductor Manufacturing Company, Ltd., Hsinchu (TW)

(72) Inventors: Chuan-Hsiang Sun, Taoyuan City (TW); Han-Lun Lee, Hsinchu County (TW); Yuan-Li Lin, Taichung City (TW); Kai-Yi Tang, New Taipei City (TW)

(73) Assignee: Taiwan Semiconductor Manufacturing Company, Ltd., Hsinchu (TW)

(21) Appl. No.: 18/940,776

(22) Filed: Nov. 7, 2024

(51) Int. Cl. G01R 31/28

(52) U.S. Cl. CPC G01R 31/2889

(57) ABSTRACT

An apparatus for probing a DUT includes a fixture disposed over the DUT, a circuitry film attached to the fixture, first probe contacts disposed on a first side of the circuitry film and extending toward the DUT, second probe contacts disposed on a second side of the circuitry film opposite to the first side and extending toward the fixture, and a first integrated device coupled to the second probe contacts and electrically coupled to the first probe contacts through the circuitry film.

### BACKGROUND

With the evolving of semiconductor technologies, integrated circuit (IC) devices get smaller and the functionalities continue to increase. The testing of the IC devices plays an important role in IC manufacturing to ensure the functionalities of the IC devices. Typically, the prober station is configured to provide the testing signals for a device-under-test (DUT) through a probe card which includes a probe head connected to a printed circuit board (PCB). Although existing methods and apparatus of testing have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1H illustrate schematic cross-sectional views of intermediate steps during a process for forming a circuitry film, in accordance with some embodiments.

FIGS. 2A-2C illustrate schematic cross-sectional views of variations of the structure in FIG. 1H, in accordance with some embodiments.

FIG. 3A is a schematic cross-sectional view of a part of a probing apparatus, in accordance with some embodiments.

FIG. 3B is a schematic view of a circuitry film in a deployment state, in accordance with some embodiments.

FIG. 4 is a schematic cross-sectional view of a probing apparatus configured to probe a device-under-test (DUT), in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation (e.g., X-direction, Y-direction, and Z-direction) depicted in the figures. The apparatus may be otherwise oriented (rotated 90 degrees or at other orientations) and the spatially relative descriptors used herein may likewise be interpreted accordingly.

Semiconductor manufacturing implements probe testing to qualify and/or sort integrated circuit (IC) devices on a wafer. In a probe test, a probing apparatus may be used and configured to couple a tester to a wafer to be tested. The probing apparatus may include a fixture, a circuitry film attached to the fixture, integrated devices (e.g., surface mount devices, integrated passive devices, and/or the like) mounted on the circuitry film, a circuit board attached to the fixture and electrically coupled to the circuitry film, and probe contacts electrically coupled to the circuitry film for testing of one or more devices-under-tests (DUTs). As the number of the DUTs increases, the density of circuits in the circuitry film and/or the number of the integrated devices may also increase. However, a large number of the integrated devices may occupy more routing area in the circuitry film. Thus, there exists a need for improved circuitry film and the integrated devices of a probing apparatus and manufacturing methods thereof.

Embodiments of the present disclosure provide a probing apparatus including a circuitry film and integrated devices coupled to an interior side of the circuitry film, and a manufacturing method of the circuitry film, where the circuitry film is a part of the apparatus for probing the DUT. For example, the circuitry film is attached to a fixture, and one or more integrated devices may be mounted on an interior side of the circuitry film facing the fixture. None or some of the integrated devices may be mounted on an exterior side of the circuitry film facing the DUT. By doing this, some embodiments of the present disclosure offer more flexible circuit routing capabilities, higher design flexibility, and better signal integrity.

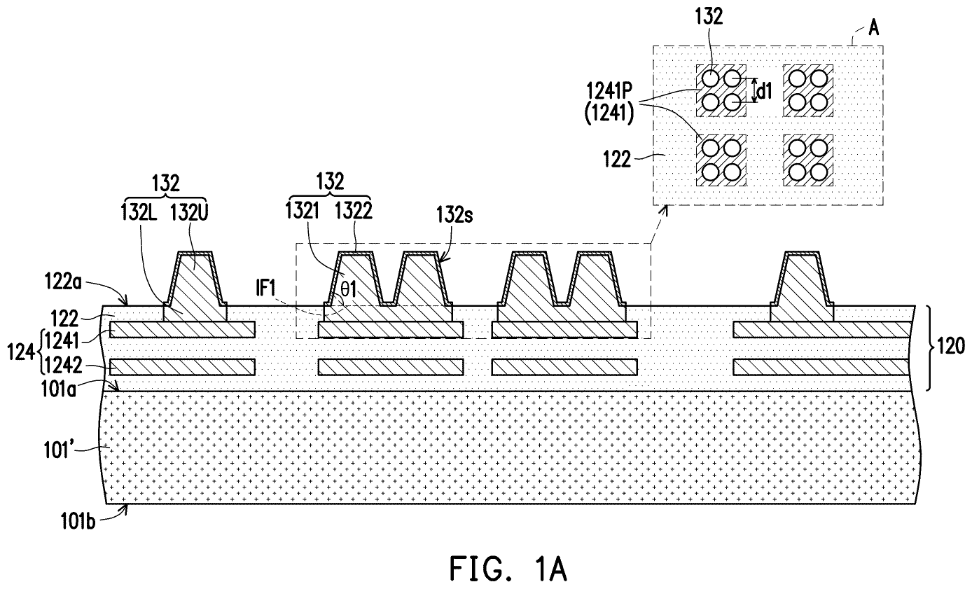

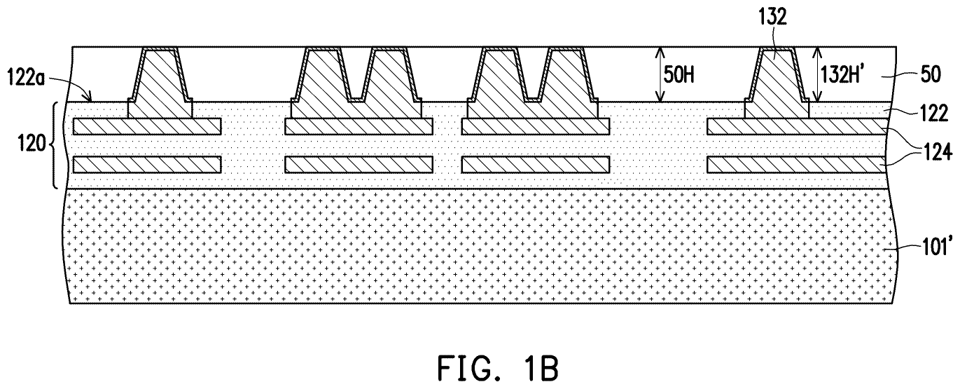

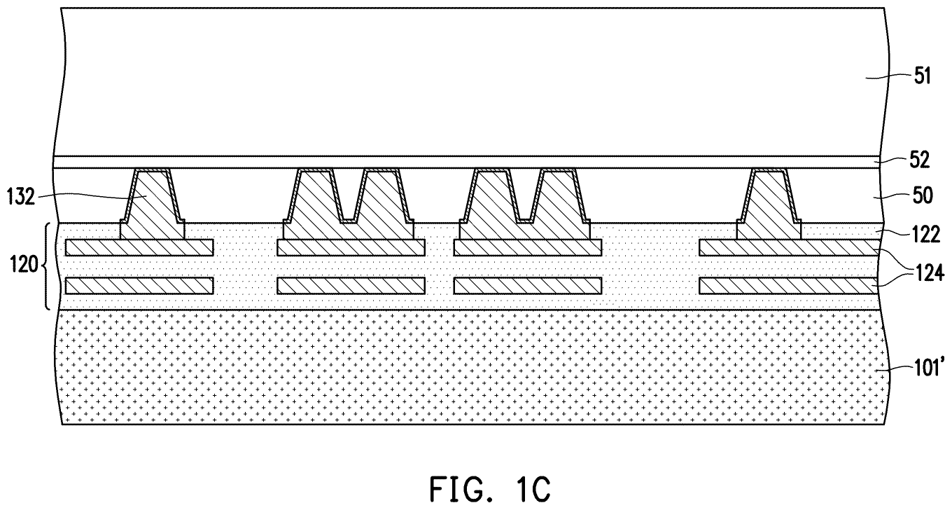

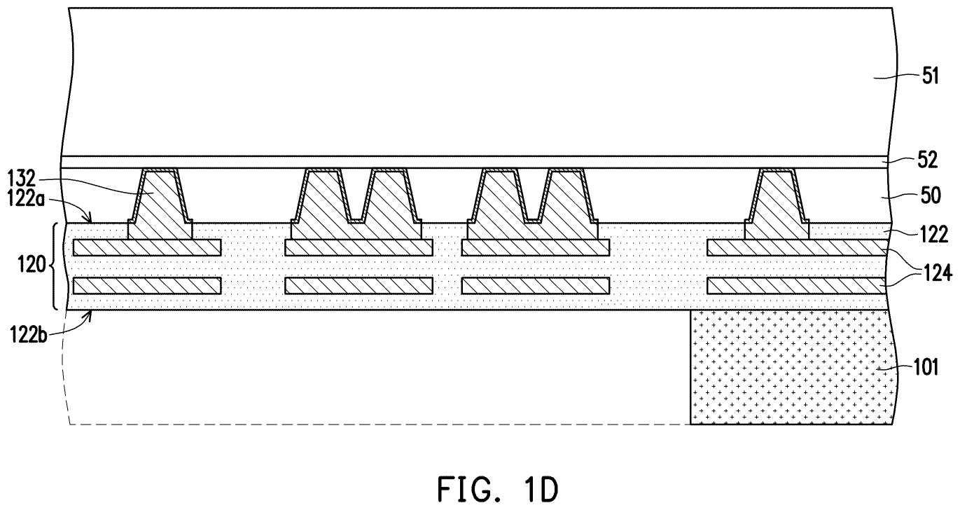

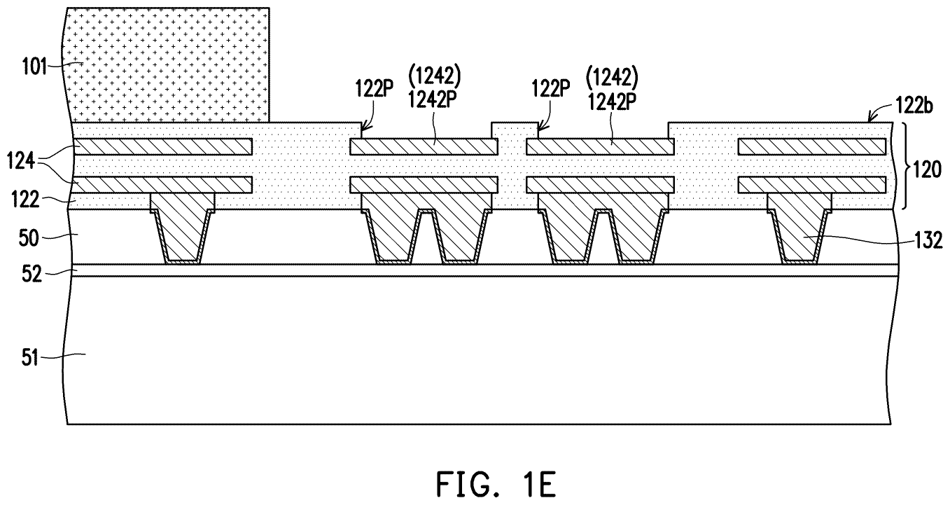

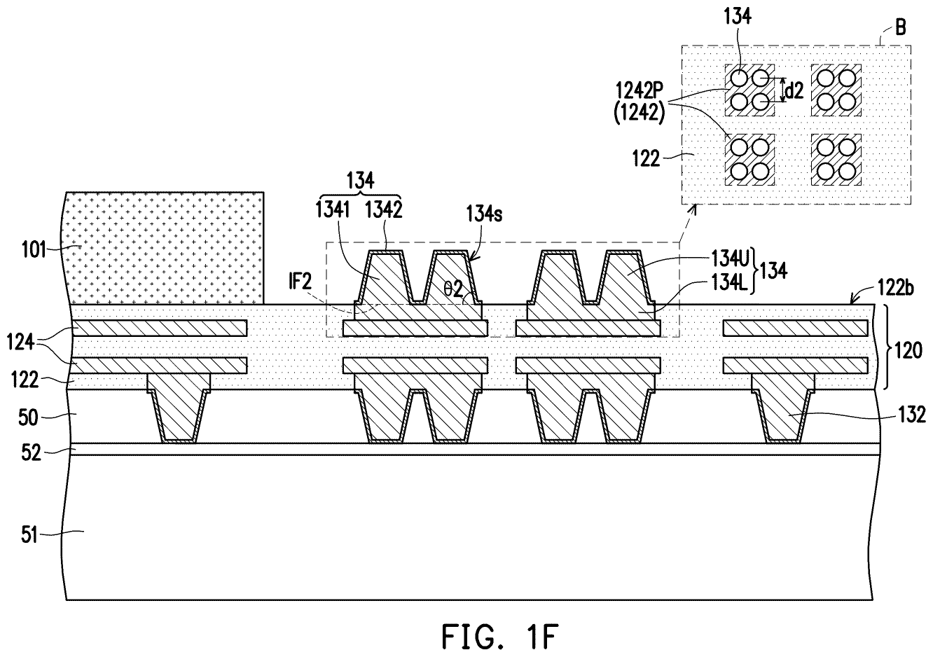

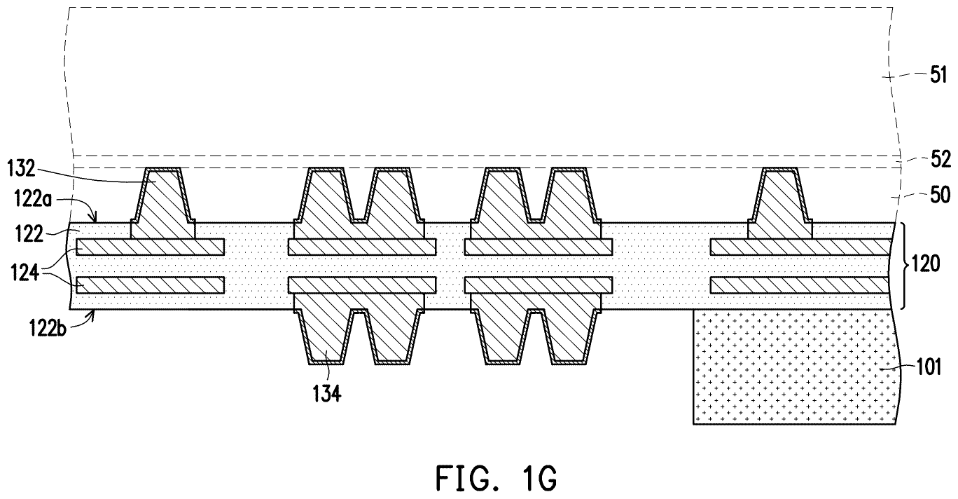

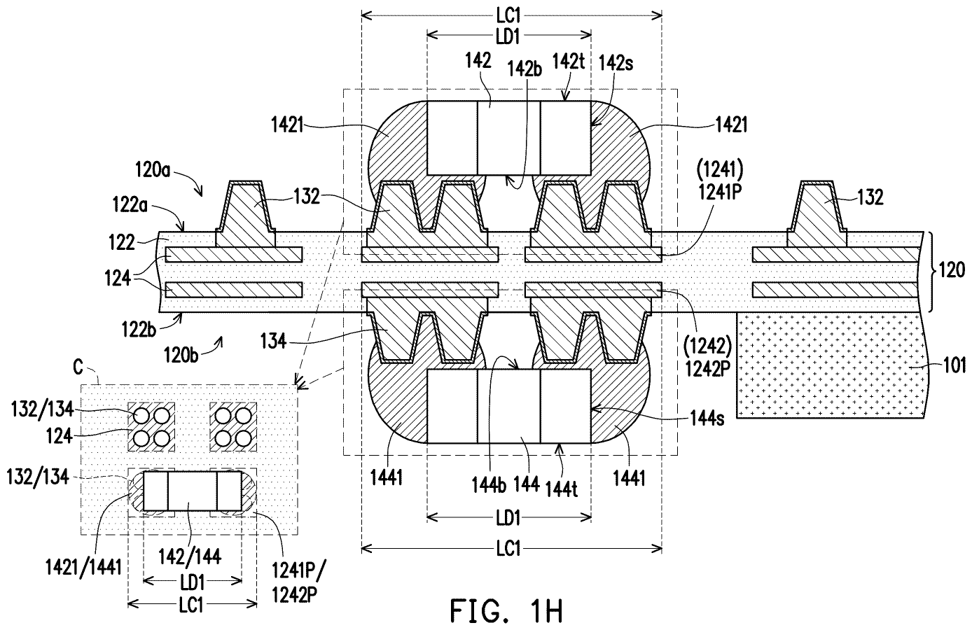

FIGS. 1A-1H illustrate schematic cross-sectional views of intermediate steps during a process for forming a circuitry film, in accordance with some embodiments. Referring to FIG. 1A, a carrier 101′ including a first side 101a and a second side 101b opposite to the first side 101a may be provided. For example, a material of the carrier 101′ includes semiconductor material(s) (e.g., silicon or the like), metal, glass, ceramic, combinations thereof, multi-layers thereof, or other suitable carrier material(s) which can support the structure subsequently formed thereon. In some embodiments, a circuitry film 120 is formed on the first side 101a of the carrier 101′. For example, the circuitry film 120 includes one or more dielectric layer(s) 122 and one or more circuit layer(s) 124 covered by the dielectric layer 122. The dielectric layer 122 may include one or more insulating material such as polyimide, benzocyclobutene, polybenzoxazole, combinations thereof, any suitable electrical isolating material(s), etc. The circuit layer 124 may be formed by one or more conductive material(s) such as copper, aluminum, nickel, gold, metal alloys, combinations thereof, any suitable materials having electrical conductivities, etc. In some embodiments, the circuit layer 124 includes transmission lines (e.g., power lines, ground lines, RF signal lines, I/O pads, and/or the like).

With continued reference to FIG. 1A, the circuity layer 124 may include a first conductive pattern 1241 and a second conductive pattern 1242 disposed between the first conductive pattern 1241 and the carrier 101′. Each of the first conductive pattern 1241 and the second conductive pattern 1242 may include conductive lines, conductive vias, conductive pads, etc. For example, the first conductive pattern 1241 and the second conductive pattern 1242 are electrically connected through conductive vias (not shown in this cross-sectional view). It is noted that that the dielectric layer 122 and the circuit layer 124 are shown for illustrative purpose only, and the number of the dielectric layer 122 and the number of the circuit layer 124 construe no limitation in the disclosure.

With continued reference to FIG. 1A, a plurality of first probe contacts 132 may be formed on the first conductive pattern 1241. In some embodiments, the respective first probe contact 132 includes a conductive body 1321 and a conductive coating 1322 covering the conductive body 1321. The material(s) of the conductive body 1321 may include copper, solder, aluminum, nickel, gold, metal alloys, combinations thereof, any suitable materials having electrical conductivities, etc. The material(s) of the conductive coating 1322 may include nickel, electroless nickel electroless palladium (ENEP), electroless nickel electroless palladium immersion gold (ENEPIG), tantalum or tantalum nitride, or the like. In some embodiments, the respective first probe contact 132 includes a lower portion 132L (e.g., the conductive body 1321) and an upper portion 132U (e.g., the conductive body 1321 and the conductive coating 1322) connected to the lower portion 132L. The lower portion 132L of the respective first probe contact 132 may be in contact with the first conductive pattern 1241 (e.g., a conductive pad 1241P) and laterally covered by the dielectric layer 122, and the upper portion 132U may be protruded from the first surface 122a of the dielectric layer 122.

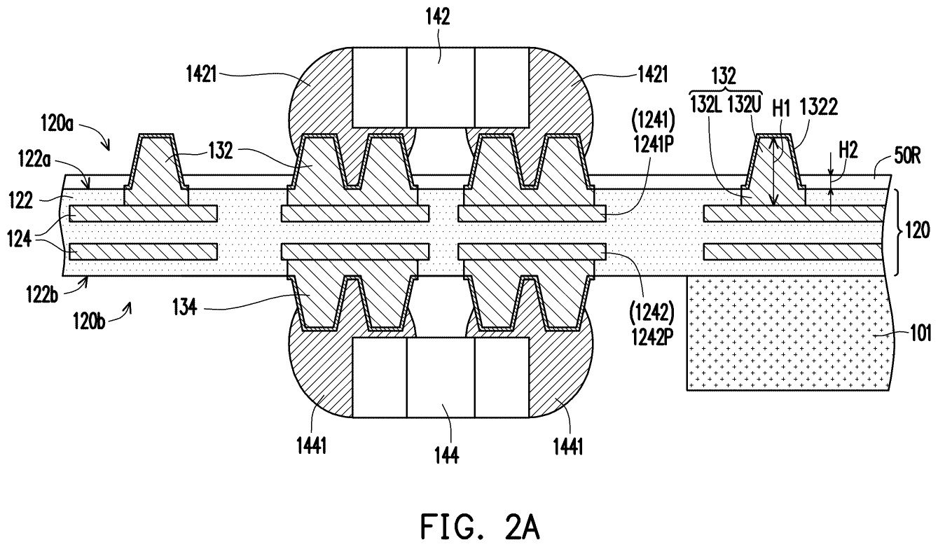

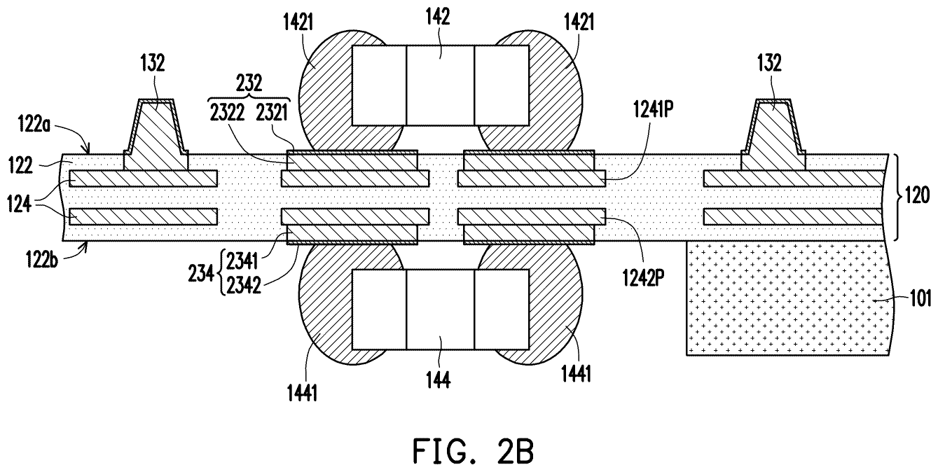

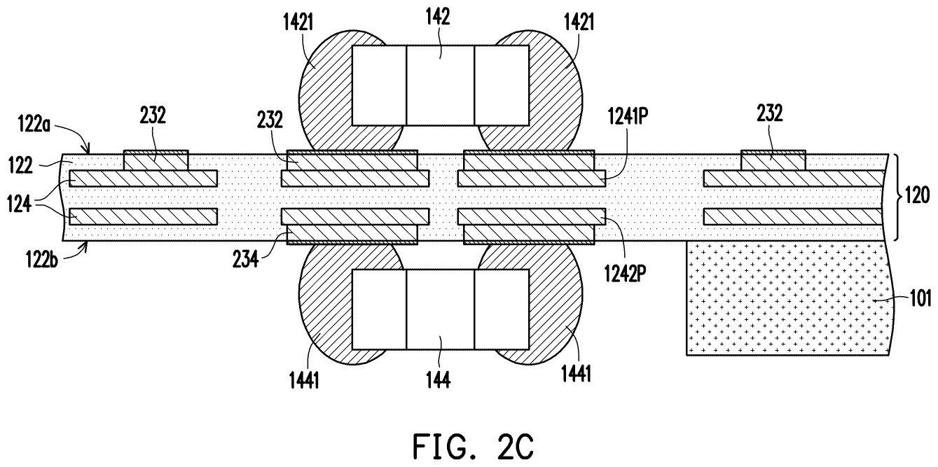

With continued reference to FIG. 1A, for the upper portion 132U of the respective first probe contact 132, the conductive coating 1322 may conformally wrap around of the conductive body 1321. In some embodiments, the lower portions 132L that land on a same conductive pad 1241P of the first conductive pattern 1241 are laterally (or continuously) connected. The upper portion 132U of the respective first probe contact 132 may have a trapezoid cross-sectional shape. For example, an included angle θ1 between the sidewall 132s of the upper portion 132U and an interface IF1 of the upper portion 132U and the lower portion 132L is an acute angle. In some embodiments, the interface IF1 is substantially coplanar with the first surface 122a of the dielectric layer 122. In some embodiments, the included angle θ1 is in a range of about 60 degrees and about 85 degrees. It is realized that the angles provided herein is an example, and may be changed to other suitable values depending on process and product requirements. By forming the upper portions 132U of the first probe contacts 132 to have a wider bottom and a narrower top, the first probe contacts 132 do not be affected by external forces and easily fall over. However, the upper portion 132U may have a different cross-sectional shape (e.g., a rectangular shape, a square shape, a polygonal shape, etc.) than shown. Alternatively, the upper portions 132U of some (or all) of the first probe contacts 132 are omitted (see FIGS. 2B-2C).

With continued reference to the simplified and enlarged top view outlined in the dashed box A in FIG. 1A, more than one (e.g., four) first probe contacts 132 may land on one conductive pad 1241P of the first conductive pattern 1241 according to some embodiments. In this manner, even if one(s) of the first probe contacts 132 is/are broken, the rest of the first probe contacts 132 may remain intact and be able to be coupled to the subsequently mounted device (see FIG. 1H), thereby improving yield results. In some embodiments, a pitch d1 between adjacent two of the first probe contacts 132 on the same conductive pad 1241P is less than about 180 microns. It is realized that the pitch value provided herein is an example, and may be changed to other suitable values depending on process and product requirements.

Referring to FIG. 1B and with reference to FIG. 1A, a sacrificial dielectric layer 50 may be formed on the circuitry film 120 and cover the first probe contacts 132. For example, the sacrificial dielectric layer 50 is formed on the first surface 122a of the dielectric layer 122 to embed the first probe contacts 132 therein for protection. In some embodiments, the maximum thickness 50H of the sacrificial dielectric layer 50 is substantially equal to or greater than the maximum height 132H′ of the respective first probe contact 132 protruded from the first surface 122a of the dielectric layer 122. The sacrificial dielectric layer 50 may be considered sacrificial in the sense that it may be ultimately removed (see FIG. 1G). In some embodiments, the material of the sacrificial dielectric layer 50 includes polyimide, benzocyclobutene, polybenzoxazole, the like, a combination thereof, or any suitable sacrificial dielectric material(s). In some embodiments, the sacrificial dielectric layer 50 is made of one or more photoresist material(s). The sacrificial dielectric layer 50 may be formed by depositing one or more sacrificial dielectric material(s) on the circuitry film 120. The sacrificial dielectric material(s) may be provided in a liquid form or a semi-liquid form. A curing step is optionally performed to cure and solidify the sacrificial dielectric material(s) so as to form the sacrificial dielectric layer 50. The curing may be a thermal curing, a UV curing, the like, or a combination thereof.

Referring to FIG. 1C and with reference to FIG. 1B, a temporary carrier 51 may be bonded to the sacrificial dielectric layer 50. In some embodiments, the temporary carrier 51 is provided with a temporary bonding layer 52, and the temporary carrier 51 is bonded to the sacrificial dielectric layer 50 through the temporary bonding layer 52. The temporary carrier 51 may include semiconductor material(s) (e.g., silicon or the like), metal, glass, ceramic, combinations thereof, multi-layers thereof, or other suitable carrier material(s) which can support the structure subsequently formed thereon. In some embodiments, the material of the temporary carrier 51 and the material of the carrier 101′ are substantially the same. Alternatively, the temporary carrier 51 has a different material than the carrier 101′. The temporary bonding layer 52 may include a polymer adhesive layer (e.g., die attach film (DAF)), a ultra-violet (UV) cured layer, such as a light-to-heat conversion (LTHC) release coating, UV glue, which reduces or loses its adhesiveness when exposed to a radiation source (e.g., UV light or a laser), any suitable temporary adhesive, and/or the like. In some embodiments, the temporary carrier 51 is a silicon substrate, and the temporary bonding layer 52 includes a silicon-containing dielectric material (e.g., silicon oxide, silicon nitride, etc.) or other suitable dielectric material(s) used for bonding the temporary carrier 51 to the sacrificial dielectric layer 50.

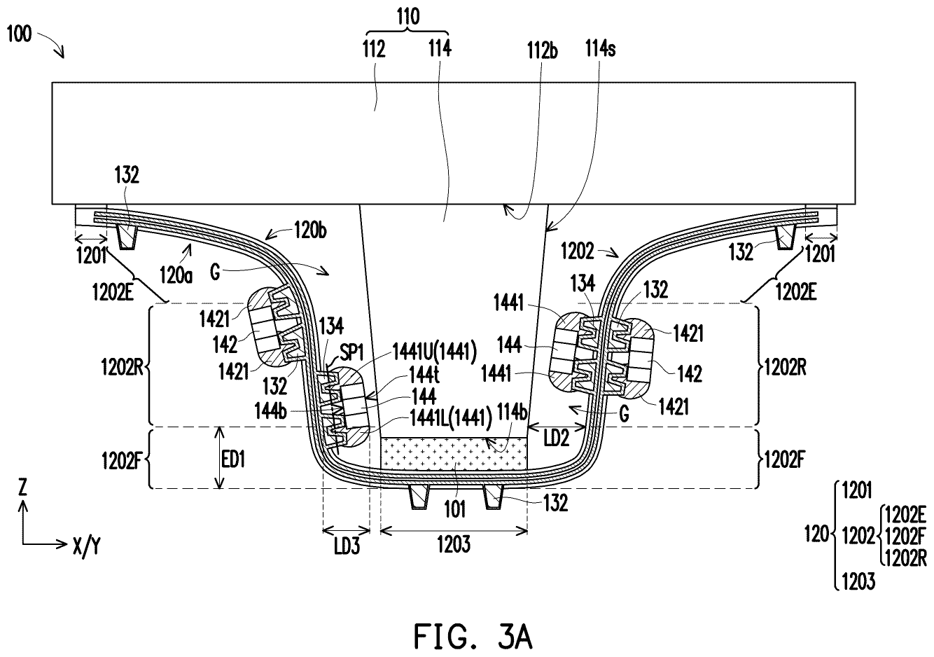

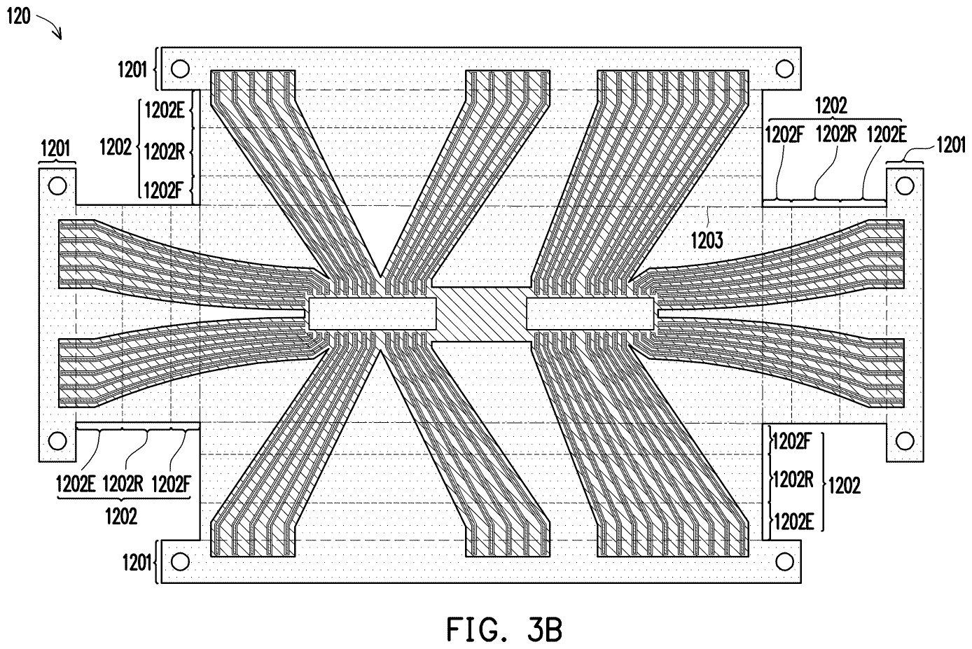

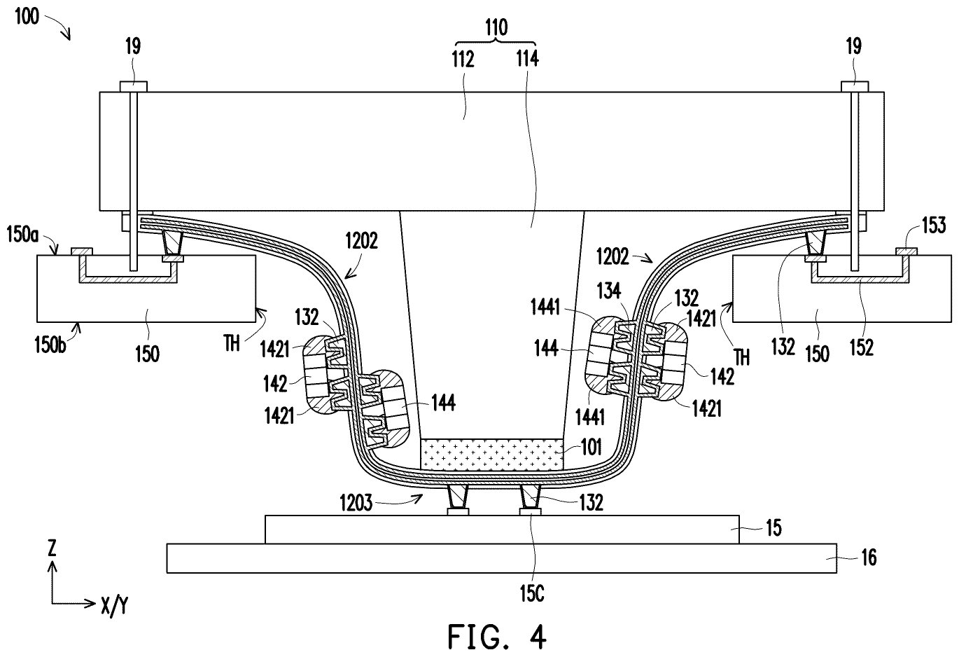

Referring to FIGS. 1D-1E and with reference to FIG. 1C, the carrier 101′ may be partially removed to form a carrier 101. The carrier 101 may be subsequently attached to a fixture of a probing apparatus (see FIGS. 3A and 4). For example, a sawing process is performed on the carrier 101′ to remove the redundant portion of the carrier 101′, leaving the carrier 101 underlying the circuitry film 120. Other suitable removal process may be used to partially remove the carrier 101′. After forming the carrier 101, the second surface 122b of the dielectric layer 122 opposite to the first surface 122a may be accessibly and partially revealed. The structure shown in FIG. 1D may be flipped over. Next, one or more opening(s) 122P may be formed in the dielectric layer 122 from the second surface 122b to accessibly reveal the second conductive pattern 1242 (e.g., conductive pads 1242P) of the circuity layer 124 for further electrical connection. The openings 122P may be formed by a laser drilling process, a lithography and etching process, or other suitable removal process, depending on the material(s) of the dielectric layer 122.

Referring to FIG. 1F and with reference to FIG. 1E and FIG. 1A, a plurality of second probe contacts 134 may be formed in the openings 122P and on the second conductive pattern 1242 (e.g., the conductive pads 1242P). The second probe contacts 134 may be similar to the first probe contacts 132 described in FIG. 1A. For example, the respective second probe contact 134 includes a conductive body 1341 and a conductive coating 1342 covering the conductive body 1341. The materials of the conductive body 1341 and the conductive coating 1342 may be similar to the conductive body 1321 and the conductive coating 1322, respectively. The lower portion 134L (e.g., the conductive body 1341) of the respective second probe contact 134 may be in contact with the second conductive pattern 1242 (e.g., the conductive pad 1242P) and laterally covered by the dielectric layer 122. The upper portion 134U (e.g., the conductive body 1341 and the conductive coating 1342) of the respective second probe contact 134 connected to the lower portion 134L may be protruded from the second surface 122b of the dielectric layer 122. For the upper portion 134U of the respective second probe contact 134, the conductive coating 1342 may conformally wrap around the conductive body 1341. In some embodiments, the lower portions 134L that land on the same conductive pad 1242P of the second conductive pattern 1242 are laterally (or continuously) connected.

With reference to FIG. 1F, the upper portion 134U of the second probe contact 134 may be formed as a stable structure such as having a trapezoid cross-sectional shape. For example, an included angle θ2 between the sidewall 134s of the upper portion 134U and an interface IF2 of the upper portion 134U and the lower portion 134L is an acute angle. The interface IF2 may be substantially coplanar with the second surface 122b of the dielectric layer 122. In some embodiments, the included angle θ2 is in a range of about 60 degrees and about 85 degrees. It is realized that the angles provided herein is an example, and may be changed to other suitable values depending on process and product requirements. However, the upper portion 134U of the second probe contact 134 may have a different cross-sectional shape (e.g., a rectangular shape, a square shape, a polygonal shape, etc.) than shown. Alternatively, the upper portions 134U of some (or all) of the second probe contacts 134 are omitted (see FIGS. 2B-2C).

With continued reference to the simplified and enlarged top view outlined in the dashed box B in FIG. 1F, more than one (e.g., four) second probe contacts 134 may land on one conductive pad 1242P of the second conductive pattern 1242 according to some embodiments. In this manner, even if one(s) of the second probe contacts 134 is/are broken, the rest of the second probe contacts 134 may remain intact and be able to be coupled to the subsequently mounted device (see FIG. 1H), thereby improving yield results. In some embodiments, a pitch d2 between adjacent two of the second probe contacts 134 on the same conductive pad 1242P is less than about 180 microns. It is realized that the value provided herein is an example, and may be changed to other suitable values depending on process and product requirements.

Referring to FIG. 1G and with reference to FIG. 1F, after forming the second probe contacts 134, the structure of FIG. 1F may be flipped over. The sacrificial dielectric layer 50 and the temporary carrier 51 along with the temporary bonding layer 52 may be removed to expose the first probe contacts 132 and the first surface 122a of the dielectric layer 122 of the circuitry film 120. In some embodiments, the temporary carrier 51 is de-bonded from the sacrificial dielectric layer 50 by a de-bonding process. For example, the de-bonding process includes projecting a light (e.g., a laser light or an UV light) on the temporary bonding layer 52, so that the temporary bonding layer 52 may decompose under the heat of the light, and the temporary carrier 51 may thus be removed. Other de-bonding process may be used depending on the material(s) of the temporary bonding layer 52. The sacrificial dielectric layer 50 may be partially or entirely removed after removing the temporary carrier 51. In some embodiments, the sacrificial dielectric layer 50 is removed by etching (e.g., a dry etch, a wet etch, and/or other etching methods.). For example, a plasma etching process is performed on the sacrificial dielectric layer 50. In some embodiments where the sacrificial dielectric layer 50 is a photoresist material, the sacrificial dielectric layer 50 is removed by exposure and development processes. Depending on the material(s) of the sacrificial dielectric layer 50, other suitable removal method may be used.

Referring to FIG. 1H and with reference to FIG. 1G, one or more first integrated device(s) 142 may be disposed over and electrically coupled to the circuity layer 124 of the circuitry film 120 through a portion of the first probe contacts 132. The other portion of the first probe contacts 132 not coupled to the first integrated devices 142 may be configured to probe the DUT and/or connected to a circuit board (see FIG. 4). One or more second integrated device(s) 144 may be disposed over and electrically coupled to the circuity layer 124 of the circuitry film 120 through the second probe contacts 134. For example, the respective first integrated device 142 is coupled to the portion of the first probe contacts 132 through first solder joints 1421. The respective first solder joint 1421 may cover the bottom surface 142b of the corresponding first integrated device 142 facing the first probe contacts 132. In some embodiments, the respective first solder joint 1421 extends to cover the sidewall 142s of the corresponding first integrated device 142 connected to the bottom surface 142b. In some embodiments, the respective first solder joint 1421 extends further to cover the top surface 142t of the corresponding first integrated device 142 connected to the sidewall 142s (see FIGS. 2B-2C). In some embodiments, each of the first solder joints 1421 is formed over one of the conductive pad 1241P of the first conductive pattern 1241, as shown in the simplified and enlarged top view outlined in the dashed box C. For example, the respective first solder joint 1421 covers at least one (e.g., one, two, three, or four) of the first probe contacts 132 formed on the conductive pad 1241P.

With continued reference to FIG. 1H, the respective second integrated device 144 may be coupled to the second probe contacts 134 through second solder joints 1441. For example, the respective second solder joint 1441 covers the bottom surface 144b of the corresponding second integrated device 144 facing the second probe contacts 134. In some embodiments, the respective second solder joint 1441 extends to cover the sidewall 144s of the corresponding second integrated device 144 connected to the bottom surface 144b. In some embodiments, the respective second solder joint 1441 extends further to cover the top surface 144t of the corresponding second integrated device 144 connected to the sidewall 144s (see FIGS. 2B-2C). Each of the second solder joints 1422 may be formed over one of the conductive pad 1242P of the second conductive pattern 1242, as shown in the simplified and enlarged top view outlined in the dashed box C. The respective second solder joint 1422 may cover at least one (e.g., one, two, three, or four) of the second probe contacts 134 formed on the conductive pad 1242P.

With continued reference to FIG. 1H, in some embodiments, a maximum lateral dimension (e.g., a length) LD1 of the first integrated device 142 is less than a lateral distance LC1 of a combination of the lateral dimensions of adjacent two of the conductive pads 1241P and a pitch between these two of the conductive pads 1241P. A maximum lateral dimension LD1 of the second integrated device 144 may be less than a lateral distance LC1 of a combination of the lateral dimensions of adjacent two of the conductive pads 1242P and a pitch between these two of the conductive pads 1242P. For example, the lateral dimension LD1 of the first integrated device 142 (or the second integrated device 144) is less than about 2.0 millimeters. It is realized that the value provided herein is an example, and may be changed to other suitable values depending on process and product requirements.

With continued reference to FIG. 1H, the first integrated devices 142 and/or the second integrated devices 144 may be a passive device including one or more passive elements such as resistors, capacitors, inductors, the like, or a combination thereof. For example, the first integrated devices 142 and/or the second integrated devices 144 may be a surface-mount device (SMD)/integrated passive device (IPD), and/or the like. The first integrated devices 142 and/or the second integrated devices 144 may independently function as a capacitor having different capacitance values, resonance frequencies, and/or different sizes, an inductor, or the like. In some embodiments, the first integrated devices 142 and/or the second integrated devices 144 include an active device including one or more active elements such as diodes, transistors, the like, or a combination thereof. The first integrated devices 142 coupled to one side of the circuitry film 120 and the second integrated devices 144 coupled to the opposing side of the circuitry film 120 may be the same type of electronic devices. Alternatively, the first integrated devices 142 and the second integrated devices 144 include different types of electronic devices. However, embodiments of the disclosure are not limited to the above structure, and other structures of the first/second integrated device are also applicable.

Still referring to FIG. 1H, by coupling the first integrated devices 142 and/or the second integrated devices 144 to the circuitry film 120, the signal integrity and the power integrity of the resulting probing apparatus may be improved. Although the first integrated devices 142 and the second integrated devices 144 are arranged in a symmetrical manner with respect to the circuitry film 120, the first integrated devices 142 and the second integrated devices 144 may be arranged in a staggered manner with respect to the circuitry film 120 according to some embodiments. By disposing the second integrated device(s) 144 over the second side 120b (e.g., the interior side facing away the DUT) of the circuitry film 120, the amount of the first/second integrated devices mounted on the circuitry film 120 may be increased to meet product demand without sacrifice the routing area of the circuit layer 124. The circuitry film 120 may have more flexible circuit routing capabilities, higher design flexibility, and better signal integrity. In some embodiments, the first integrated device 142 disposed over the first side 120a (e.g., the exterior side facing the DUT) of the circuitry film 120 is omitted, and all of the integrated devices are coupled to the second side 120b (e.g., the interior side facing away the DUT) of the circuitry film 120. The number of the first integrated devices 142 and the number of second integrated devices 144 may depend on product and process requirements and construe no limitation in the disclosure.

FIGS. 2A-2C illustrate schematic cross-sectional views of variations of the structure in FIG. 1H, in accordance with some embodiments. Unless specified otherwise, the components in FIGS. 2A-2C are essentially the same as the like components denoted by like reference numerals in FIG. 1H. Referring to FIG. 2A and with reference to FIG. 1H, the structure shown in FIG. 2A is similar to the structure shown in FIG. 1H, and thus the detailed descriptions are not repeated for the sake of brevity. The difference of the structures shown in FIG. 2A and FIG. 1H includes that the sacrificial dielectric layer 50 is not entirely removed after the removal process (see FIG. 1G), leaving a dielectric layer 50R covering the first surface 122a of the dielectric layer 122 of the circuitry film 120. The first probe contacts 132 on the conductive pad 1241P may include the lower portion 132L laterally covered by the dielectric layer 122, a lower part of the upper portion 132U (including the conductive coating 1322) laterally covered by the dielectric layer 50R overlying the dielectric layer 122, and an upper part of the upper portion 132U protruded from the dielectric layer 50R for further electrical connection (e.g., covered by the first solder joint 1421.

With continued reference to FIG. 2A, the sacrificial dielectric layer 50 may be partially removed to form the dielectric layer 50R having a maximum thickness H2. The maximum thickness H2 of the dielectric layer 50R may be less than a maximum height H1 of the respective first probe contact 132. For example, the maximum height H1 of the respective first probe contact 132 is measured between the bottom surface of the lower portion 132L and the top surface of the upper portion 132U. In some embodiments, a ratio of the maximum height H1 of the respective first probe contact 132 to the maximum thickness H2 of the dielectric layer 50R is in a range of about 5 and about 10. It is realized that the values provided herein are examples, and may be changed to other suitable values depending on process and product requirements.

Referring to FIG. 2B and with reference to FIG. 1H, the structure shown in FIG. 2B is similar to the structure shown in FIG. 1H, and thus the detailed descriptions are not repeated for the sake of brevity. The difference of the structures shown in FIG. 2B and FIG. 1H includes that the portion of the first probe contacts 132 which are coupled to the first integrated device 142 through the first solder joints 1421 are replaced with the first contacts 232. The second probe contacts 134 which are coupled to the second integrated device 144 through the second solder joints 1441 may (or may not) be replaced with the second contacts 234. In some embodiments, the respective second contact 234 includes the conductive body 2341 and a conductive coating 2342 covering the conductive body 2341. The materials of the conductive body 2341 and the conductive coating 2342 may be similar to the materials of the conductive body 1321 and the conductive coating 1312, respectively. For example, after forming the openings 122P in the dielectric layer 122 to accessibly reveal the conductive pads 1242P of the circuity layer 124 (see FIG. 1E), the openings 122P are filled with one or more conductive material(s) to form the conductive bodies 2341 of the second contacts 234. The conductive coating 2342 is optionally formed on the corresponding conductive body 2341. The second solder joints 1441 may land on the second contacts 234 and be coupled to the second integrated device 144 to the second contacts 234. The formation and the material of the first contacts 232 including the conductive body 2321 and the conductive coating 2322 may be similar to those of the second contacts 234, and thus the detailed descriptions are not repeated for the sake of brevity.

Referring to FIG. 2C and with reference to FIG. 2B and FIG. 1H, the structure shown in FIG. 2C is similar to the structure shown in FIG. 2B and FIG. 1G, and thus the detailed descriptions are not repeated for the sake of brevity. The difference of the structures shown in FIG. 2C and FIG. 2B includes that all of the first probe contacts 132 are replaced with the first contacts 232. As mentioned in the preceding paragraphs, the formation and the material of the first contacts 232 may be similar to those of the second contacts 234 described in FIG. 2B, and thus the detailed descriptions are not repeated for the sake of brevity.

FIG. 3A is a schematic cross-sectional view of a part of a probing apparatus and FIG. 3B is a schematic view of the circuitry film 120 in a deployment state, in accordance with some embodiments. Referring to FIGS. 3A-3B and with reference to FIG. 1H, a probing apparatus 100 may include a fixture 110 and the circuitry film 120 attached to the fixture 110. The details of the carrier 101, the circuitry film 120, the first/second probe contacts 132/134, the first/second integrated devices 142/144 may refer to the discussion associated with FIG. 1H (or FIGS. 2A-2C), and the associated components in FIGS. 3A-3B are essentially the same as the like components denoted by like reference numerals in FIG. 1H (or FIGS. 2A-2C). In some embodiments, the fixture 110 includes a base 112 and a protrusion 114 connected to the base 112. The fixture 110 may be hollow or may be solid. For example, the base 112 serving as a support element is formed of rigid material such as metal, hard dielectrics, suitable incompressible materials, combinations thereof, etc. In some embodiments, the base 112 provides a grounding path for a DUT (see FIG. 4). In some embodiments, the protrusion 114 is formed of insulating material, composite material including polymer and metal, and/or the like. The protrusion 114 may extend from the bottom surface 112b of the base 112 in the Z-direction. For example, the protrusion 114 extends downward from the bottom surface 112b of the base 112 in an inclined manner. The sidewalls 114s of the protrusion 114 may be tilted from the bottom surface 112b of the base 112. The protrusion 114 may be in the shape of an inverted trapezoid seen from the cross-sectional view. Alternatively, the cross-section of the protrusion 114 may be a U-shape, a rectangular shape, a square shape, and/or the like. The base 112 may be wider than the protrusion 114, and a portion of the bottom surface 112b of the base 112 is unmasked by the protrusion 114.

With continued reference to FIGS. 3A-3B and FIG. 1H, the circuitry film 120 may be thin and mechanically flexible. When attaching the circuitry film 120 to the fixture 110, the circuitry film 120 may be bent to substantially fit the contour of the fixture 110. In some embodiments, the circuitry film 120 does not fully match the shape of the fixture 110. The gap G may be formed between the sidewalls 114s of the protrusion 114 and the circuitry film 120. For example, the circuitry film 120 includes first portions 1201 attached to the bottom surface 112b of the base 112 that is not covered by the protrusion 114, second portions 1202 connected to the first portions 1201 and extending along the sidewalls 114s of the protrusion 114, and a third portion 1203 connected to the second portions 1202 and extending to underlie the bottom surface 114b of the protrusion 114. The first portions 1201 may be located at the periphery of the circuitry film 120 and functioning as fixing areas for affixing the circuitry film 120 to the fixture 110. The third portion 1203 may be directly over the DUT(s). In some embodiments, the carrier 101 is attached to the bottom surface 114b of the protrusion 114 for coupling the third portion 1203 of the circuitry film 120 to the protrusion 114 of the fixture 110. The carrier 101 may be attached to the protrusion 114 using any suitable means such as adhesive, mechanically securing elements (e.g., fasteners, screws, pins, rivets, etc.), and/or the like. The second portions 1202 may follow the contour of the protrusion 114 of the fixture 110 and may be referred to as bent portions.

With continued reference to FIGS. 3A-3B and FIG. 1H, the first integrated devices 142 may be disposed at the first side 120a of the circuitry film 120, and the second integrated devices 144 may be disposed at the second side 120b of the circuitry film 120. The second integrated devices 144 may be disposed inside the gap G between the circuitry film 120 and the sidewalls 114s of the protrusion 114. The respective second portion 1202 of the circuitry film 120 may include a device-mounting region 1202R within which the first/second integrated devices 142/144 are disposed. For example, the respective second portion 1202 of the circuitry film 120 includes a first excluded region 1202E connected to the first portion 1201, a second excluded region 1202F connected to the third portion 1203, and the device-mounting region 1202R connected to the first excluded region 1202E and the second excluded region 1202F.

In some embodiments, the first excluded region 1202E and the second excluded region 1202F are or include turning segments of the circuitry film 120 which are not suitable for mounting the first/second integrated devices 142/144 thereon. As compared to the first excluded region 1202E and the second excluded region 1202F, the device-mounting region 1202R is relatively flat and suitable for mounting the first/second integrated devices 142/144 thereon. The minimum lateral distance LD2 of the gap G at the boundary of the device-mounting region 1202R measured in the X-direction (or the Y-direction) may be greater than the maximum lateral distance LD3 measured between the second side 120b of the circuitry film 120 and the top surface 144t of the corresponding second integrated device 144. A vertical distance ED1 of the second excluded region 1202F measured along the Z-direction may be non-zero as shown in FIG. 3A. For example, the vertical distance ED1 of the second excluded region 1202F is greater than 0 and less than about 1 millimeters.

With continued reference to FIG. 3A, the second integrated devices 144 may be disposed within the device-mounting region 1202R. The lowest point (or the highest point) of the second integrated device 144 may not be disposed beyond the device-mounting region 1202R. For example, the lowest point (or the highest point) of the second integrated device 144 is intersected with the boundary of the device-mounting region 1202R. In such cases, the second solder joints 1441 coupling the corresponding second integrated device 144 to the second probe contacts 134 may be in the device-mounting region 1202R and may extend further into the adjacent second excluded region 1202F (or the first excluded region 1202E). In some embodiments, the second solder joints 1441 coupling the corresponding second integrated device 144 to the second probe contacts 134 have substantially a same slope SP1. A shown in the cross-sectional view of FIG. 3A, the upper one 1441U of the second solder joints 1441 may have substantially the same slope as the lower one 1441L of the second solder joints 1441. In some embodiments, the bottom surface 144b of the corresponding second integrated device 144 is inclined with the substantially same slope SP1. By forming the second solder joints (1441U and 1441L) to have the substantially same slope SP1 in the cross-sectional view, the corresponding second integrated device 144 may be firmly mounted on the circuitry film 120 through the second solder joints (e.g., 1441U and 1441L) and the second probe contacts 134, without being affected by the turning segments of the circuitry film 120.

FIG. 4 is a schematic cross-sectional view of the probing apparatus 100 configured to probe a DUT, in accordance with some embodiments. Referring to FIG. 4 and with reference to FIGS. 3A-3B, the probing apparatus 100 includes the fixture 110, the circuitry film 120 attached to the fixture 110, and the circuit board 150 attached to the fixture 110 through one or more securing element(s) 19 (e.g., fasteners, screws, clamps, pins, rivets, other suitable engaging means, etc.). For example, the base 112 of the fixture 110 includes receiving openings at desirable locations, so that screws may be screwed through the receiving openings of the fixture 110 to be affixed onto the circuit board 150. Other suitable engaging manner may be employed as long as the engaging mechanism may be stably engaged with the fixture 110. The base 112 of the fixture 110 may be disposed above the top surface 150t of the circuit board 150 and across the through hole TH of the circuit board 150. The protrusion 114 of the fixture 110 may pass through the through hole TH of the circuit board 150. In some embodiments, the bottom surface 114b of the protrusion 114 extends lower than the bottom surface 150b of the circuit board 150, so that the first probe contacts 132 on the third portion 1203 of the circuitry film 120 and below the bottom surface 114b of the protrusion 114 may probe the DUT 15 without being interfered.

With continued reference to FIG. 4, the circuit board 150 may be or may include a printed circuit board (PCB) including a plurality of signal channels 152 to provide electrical interconnection. For example, the signal channels 152 include conductive lines, conductive pads, conductive vias, plated through holes, and/or the like. The signal channels 152 may be electrically coupled to the conductive contacts 153 on the circuit board 150 for transmitting signals to/from the external device. In some embodiments, the circuit board 150 is laminated with epoxy resin with the conductive layers formed therein, where the conductive layers may be formed from metal (e.g., copper foil) and may be patterned to form the signal channels 152. In some embodiments, after assembling the fixture 110 to the circuit board 150, a portion of the first probe contacts 132 on the second portions 1202 of the circuitry film 120 may serve as signal connectors and may be in physical and electrical contact with the signal channels 152 of the circuit board 150. As shown in FIG. 4, a portion of the first probe contacts 132 landing on the second portions 1202 of the circuitry film 120 may be disposed in the gap and extend between the base 112 of the fixture 110 and the circuit board 150 along the Z-direction.

As mentioned in the preceding paragraphs associated with FIG. 3A, the circuitry film 120 may be bent to substantially fit the contour of the fixture 110. The carrier 101 may be interposed between the third portion 1203 of the circuitry film 120 and the bottom surface 114b of the protrusion 114. For example, the carrier 101 is attached to the bottom surface 114b of the protrusion 114 through any suitable means. The details of the carrier 101, the circuitry film 120, the first/second probe contacts 132/134, the first/second integrated devices 142/144 may refer to the discussion associated with FIG. 1H (or FIGS. 2A-2C), and the associated components in FIGS. 3A-3B are essentially the same as the like components denoted by like reference numerals in FIG. 1H (or FIGS. 2A-2C).

With continued reference to FIG. 4, the DUT 15 may be mounted on a chuck 16 during probe testing. For example, the chuck 16 which supports the DUT 15 is configured to move the DUT 15. The chuck 16 may be moved in any direction (e.g., x, y, z, tilt angle, etc.) through suitable moving mechanism (not shown) in order to bring the contact points 15C of the DUT 15 into engagement with the first probe contacts 132 on the third portion 1203 of the circuitry film 120. The contact points 15C may be or may include contact pads, metal bumps, solder balls, etc. In some embodiments, the DUT 15 is a semiconductor wafer including a plurality of dies (not shown). The first probe contacts 132 on the third portion 1203 of the circuitry film 120 may be in contact with the contact points 15C of each die of the semiconductor wafer for testing. Although a single DUT is shown in FIG. 4, it should be noted that a plurality of the DUTs 15 may be disposed on the chuck 16 for the probe testing.

In some embodiments, a method for probing the DUT 15 includes providing the probing apparatus 100 and probing the DUT 15 through the first probe contacts 132 on the third portion 1203 of the circuitry film 120. The step of providing the probing apparatus 100 may include: forming the circuitry film 120; forming the first probe contacts 132 on the first side 120a of the circuitry film 120; forming the second probe contacts 134 on the second side 120b of the circuitry film 120; coupling the second integrated device 144 to the second probe contacts 134 through the second solder joints 1441, where the second integrated device 144 is electrically coupled to the first probe contacts 132 through the circuitry film 120; attaching the circuitry film 120 to the fixture 110; and attaching the circuit board 150 to the fixture 110, where the protrusion 114 of the fixture 110 passes through the circuit board 150, and the circuit board 150 is electrically coupled to the first probe contacts 132 through the circuitry film 120. During the testing, the first probe contacts 132 on the third portion 1203 of the circuitry film 120 may be in physical and electrical contact with the contact points 15C of the DUT 15. For example, the signals to/from the tester (not shown) is transmitted via the circuit board 150 and the circuitry film 120 to the first probe contacts 132 on the third portion 1203 of the circuitry film 120.

The probing apparatus 100 may include more than one integrated device (e.g., 142 and 144) mounted on the circuitry film 120. The integrated devices may be or include SMDs, IPDs, and/or the like. In some cases, the use of the integrated devices may provide improved voltage or current stability for the circuitry film 120. In some cases, the integrated devices may be configured to tune the output voltage to suppress the signal and power noises, and the signal integrity and the power integrity of the circuitry film 120 may be improved, thereby enhancing performance efficiency thereof. For example, some (or all) of the integrated devices (e.g., 144) are mounted on the interior side of the circuitry film 120 facing the fixture 110. By disposing the second integrated devices 144 at the second side 120b (e.g., the interior side facing the fixture 110) of the circuitry film 120, the amount of the first/second integrated devices 142/144 mounted on the circuitry film 120 may be increased to meet product demand without occupying additional routing area of the circuit layer 124. The circuitry film 120 may have more flexible circuit routing capabilities, higher design flexibility, and better signal integrity.

It is appreciated that in this written description, as well as in the claims below, the terms “first”, “second”, “third”, etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first integrated device” in the claims may not necessarily correspond to the “first integrated devices”in the illustrated embodiment.

According to some embodiments, an apparatus for probing a DUT includes a fixture disposed over the DUT, a circuitry film attached to the fixture, first probe contacts disposed on a first side of the circuitry film and extending toward the DUT, second probe contacts disposed on a second side of the circuitry film opposite to the first side and extending toward the fixture, and a first integrated device coupled to the second probe contacts and electrically coupled to the first probe contacts through the circuitry film.

According to some embodiments, an apparatus for probing a DUT includes a fixture disposed over the DUT, a circuitry film disposed along a contour of the fixture, probe contacts disposed on an exterior side of the circuitry film and facing the DUT, first contacts disposed on an interior side of the circuitry film and angularly offset from an extending direction of the probe contacts, a first integrated device disposed in a gap between a sidewall of the fixture and the circuitry film and coupled to the first contacts through first solder joints. The first integrated device is electrically coupled to the probe contacts through the circuitry film.

According to some embodiments, a method for probing a DUT includes providing a probing apparatus and probing the DUT by probe contacts. Providing the probing apparatus includes: forming a circuitry film; forming the probe contacts on a first side of the circuitry film; forming first contacts on a second side of the circuitry film opposite to the first side; coupling a first integrated device to the first contacts through first solder joints, where the first integrated device is electrically coupled to the probe contacts through the circuitry film; attaching the circuitry film to a fixture; and attaching a circuit board to the fixture, where a protrusion of the fixture passes through the circuit board, and the circuit board is electrically coupled to the probe contacts through the circuitry film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus for probing a device-under-test (DUT), comprising:
a fixture disposed over the DUT;
a circuitry film attached to the fixture;
first probe contacts disposed on a first side of the circuitry film and extending toward the DUT;
second probe contacts disposed on a second side of the circuitry film opposite to the first side and extending toward the fixture; and
a first integrated device coupled to the second probe contacts and electrically coupled to the first probe contacts through the circuitry film.

2. The apparatus of claim 1, further comprising:
third probe contacts disposed on the first side of the circuitry film and angularly offset from an extending direction of the first probe contacts; and
a second integrated device coupled to the third probe contacts and electrically coupled to the first probe contacts through the circuitry film.

3. The apparatus of claim 1, further comprising:
a circuit board electrically coupled to the circuitry film, wherein a base of the fixture is engaged with the circuit board and a protrusion of the fixture connected to the base passes through the circuit board; and
fourth probe contacts disposed on the first side of the circuitry film and being in contact with the circuit board, wherein the circuit board is electrically coupled to the first probe contacts through the fourth probe contacts and the circuitry film.

4. The apparatus of claim 1, wherein the circuitry film comprises:
a first portion attached to a base of the fixture;
a second portion attached to a protrusion of the fixture connected to the base; and
a third portion connected to the first and second portions and extending along a sidewall of the protrusion, the third portion comprising a device-mounting region and excluded regions connected to the device-mounting region and the first and second portions, wherein the circuitry film comprises turning segments in the excluded regions, and the first integrated device is mounted on the device-mounting region.

5. The apparatus of claim 4, wherein:
the first integrated device is coupled to the second probe contacts through solder joints, and
the first integrated device is within a boundary of the device-mounting region, and one of the solder joints is in the device-mounting region and extends into one of the excluded regions.

6. The apparatus of claim 1, wherein the first integrated device is coupled to the second probe contacts through solder joints and the solder joints have substantially a same slope in a cross-sectional view.

7. The apparatus of claim 1, wherein:
a gap is between the circuitry film and a sidewall of the fixture, and
a minimum lateral distance of the gap at a boundary of a region on which the first integrated device is disposed is greater than a maximum lateral distance between the second side of the circuitry film and a top surface of the corresponding first integrated device.

8. The apparatus of claim 1, wherein the first integrated device is coupled to the second probe contacts through solder joints, a plurality of the second probe contacts land on a conductive pad of the circuitry film, and one of the solder joints is coupled to at least one of the plurality of the second probe contacts.

9. The apparatus of claim 1, wherein the first integrated device is coupled to the second probe contacts through solder joints, a bottom surface of the first integrated device facing the second probe contacts and a sidewall of the first integrated device connected to the bottom surface are covered by the solder joints.

10. The apparatus of claim 1, wherein at least one of the second probe contacts comprises:
a first portion connected to a conductive pad of the circuitry film and laterally covered by a dielectric layer of the circuitry film; and
a second portion connected to the first portion and protruded from the dielectric layer of the circuitry film, the second portion being covered by a first solder joint coupling the first integrated device to the second probe contacts.

11. An apparatus for probing a device-under-test (DUT), comprising:
a fixture disposed over the DUT;
a circuitry film disposed along a contour of the fixture, wherein a gap is between a sidewall of the fixture and the circuitry film;
probe contacts disposed on an exterior side of the circuitry film and facing the DUT;
first contacts disposed on an interior side of the circuitry film and angularly offset from an extending direction of the probe contacts; and
a first integrated device disposed in the gap and coupled to the first contacts through first solder joints, and the first integrated device being electrically coupled to the probe contacts through the circuitry film.

12. The apparatus of claim 11, further comprising:
second contacts disposed on the exterior side of the circuitry film and angularly offset from the extending direction of the probe contacts; and
a second integrated device coupled to the second contacts and electrically coupled to the probe contacts through the circuitry film.

13. The apparatus of claim 11, wherein at least one of the first contacts comprises:
a conductive body landing on a conductive pad of the circuitry film, the conductive body comprising a lower portion laterally covered by a dielectric layer of the circuitry film and an upper portion protruded from the dielectric layer of the circuitry film; and
a conductive coating conformally covering the upper portion of the conductive body.

14. The apparatus of claim 13, wherein:
additional dielectric layer overlying the dielectric layer of the circuitry film, and
a lower portion of the conductive coating is laterally covered by the additional dielectric layer.

15. The apparatus of claim 11, wherein at least one of the first contacts comprises:
a conductive body landing on a conductive pad of the circuitry film and disposed in an opening of a dielectric layer of the circuitry film; and
a conductive coating overlying the conductive body, wherein a height of the at least one of the first contacts is less than a height of the probe contacts.

16. The apparatus of claim 11, wherein:
a first portion of the first contacts lands on a first conductive pad of the circuitry film, and a second portion of the first contacts lands on a second conductive pad of the circuitry film that is laterally spaced apart from the first conductive pad, and
a lateral dimension of the first integrated device is less than a total lateral distance of a lateral dimension of the first conductive pad, a lateral dimension of the second conductive pad, and a pitch between the first and second conductive pads.

17. A method for probing a device-under-test (DUT), comprising:
providing a probing apparatus comprising:
forming a circuitry film;
forming probe contacts on a first side of the circuitry film;
forming first contacts on a second side of the circuitry film opposite to the first side;
coupling a first integrated device to the first contacts through first solder joints, wherein the first integrated device is electrically coupled to the probe contacts through the circuitry film;
attaching the circuitry film to a fixture; and
attaching a circuit board to the fixture, wherein a protrusion of the fixture passes through the circuit board, and the circuit board is electrically coupled to the probe contacts through the circuitry film; and
probing the DUT by the probe contacts.

18. The method of claim 17, wherein providing the probing apparatus further comprises:
forming the circuitry film on a carrier;
partially removing the carrier to expose the second side of the circuitry film before forming the first contacts on the interior side of the circuitry film; and
attaching the circuitry film to the fixture after coupling the first integrated device to the first contacts, wherein a remaining portion of the carrier is interposed between the protrusion of the fixture and the circuitry film.

19. The method of claim 17, wherein providing the probing apparatus further comprises:
forming a sacrificial dielectric layer on the first side of the circuitry film to cover the probe contacts;
bonding a temporary carrier to the sacrificial dielectric layer;
forming the first contacts on the second side of the circuitry film by using the temporary carrier as a support; and
de-bonding the temporary carrier before coupling the first integrated device to the first contacts.

20. The method of claim 17, wherein providing the probing apparatus further comprises:
forming second contacts on the first side of the circuitry film when forming the probe contacts on the first side of the circuitry film;
coupling a second integrated device to the second contacts through second solder joints before attaching the circuitry film to the fixture, wherein the second integrated device is electrically coupled to the probe contacts through the circuitry film.
